(19) United States
(12) Patent Application Publication
(10) Pub. No.: US 2007/0200199 A1
(43) Pub. Date: Aug. 30, 2007

(54) Semiconductor bulk resistance element

(76) Inventors: Susumu Murakami, Hitachinaka (JP); Takeo Nonaka, Minamiarupusu (JP); Shinji Naito, Kai (JP); Minoru Nakamura, Hitachinaka (JP); Hiroshi Hozoji, Hitachiota (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/655,232

(22) Filed: Jan. 19, 2007

(30) Foreign Application Priority Data
Feb. 24, 2006 (JP) 2006-047964

(51) Int. Cl. H01L 29/00

(52) U.S. Cl. 257/536

(57) ABSTRACT

Providing a technology capable of obtaining a desired resistance value through preferable controllability, and improving linearity between voltage and current. A semiconductor bulk resistance element of the present invention comprise a semiconductor chip having a main surface (first main surface), and on the first main surface of a semiconductor resistor layer (an n−type semiconductor region) to work as a bulk resistor, a guard ring layer (a p+ type semiconductor region) of a conductive type opposite to the semiconductor resistor layer is formed, and a contact layer (an n++ type semiconductor region) that goes through the guard ring layer and is of a conductive type same as the semiconductor resistor layer, has a higher impurity concentration than that of the semiconductor resistor layer and the guard ring layer is formed, and on the top of the contact layer and at the bottom of the semiconductor resistor layer, semiconductor regions (n++ type semiconductor regions) that have ohmic contact with electrodes and are of a conductive type same as the semiconductor resistor layer, and has an impurity concentration same as or higher than that of the contact layer are adjacently arranged respectively.

### CROSS-REFERENCE TO RELATED APPLICATION

The present application claims priority from Japanese patent application No. JP 2006-047964 filed on Feb. 24, 2006, the content of which is hereby incorporated by reference into this application.

### TECHNICAL FIELD OF THE INVENTION

The present invention relates to a technology especially effective when applied to a module comprising a resistance element using a semiconductor bulk and a semiconductor bulk resistance element, more specifically to a technology effective when applied to, for an example, a diode module having a semiconductor bulk resistance element.

### BACKGROUND OF THE INVENTION

As a resistor body using a semiconductor bulk, there has been known a resistor formed in parallel with an active element such as a diode, a bipolar transistor, a MOS transistor, a thyristor and the like. For example, in the semiconductor device described in Japanese Patent Laid-Open Publication No. 6-342878 (Patent Document 1), a p−type impurity introduction region of a plane closed-loop shape going along a chip division end is formed on the front surface side of an n−type semiconductor substrate on which a back surface electrode is formed, so that the measured value of diffusion resistance at wafer process stage should become close to the measured value after scribing, and at the center portion thereof, there is a non-introduction region. A front surface electrode (first main surface electrode) is conductively contacted onto the surfaces of the p−type impurity introduction region and the impurity non-introduction region at the center portion thereof, and a back surface electrode is formed on the n−type semiconductor substrate of the back surface. Since the impurity introduction region is plane closed loop shape, and the surface at the center portion of the semiconductor substrate surrounded by the loop is an electrode contact region at one of vertical type diffusion resistance regions, it is described that the vertical type diffusion resistance region is not formed unevenly at the chip division end, and a vertical diffusion resistance region that is considered to be symmetrical to the substrate thickness direction and not to reach the chip division end is formed.

Further, in the resistor device described in Japanese Patent Laid-Open Publication No. 56-94653 (Patent Document 2), a hardly conductive thin film is made to intermediate on connective portion between conductive bodies, thereby it is described that it is possible to provide a resistor device with a small occupying area.

### SUMMARY OF THE INVENTION

In the former of the prior technique, since consideration for variation of resistance value caused by reduction of contact resistance between the electrode and the semiconductor and a pinch effect of the impurity introduction region of the plane closed-loop shape is not made, there is a problem that if a voltage is applied between two electrodes, the resistance value varies due to variation in voltage value and changes of the electrode polarities.

According to examinations made by the present inventors, in the above prior technique, for example, just under the front surface electrode, the n−type semiconductor region existing between the plane closed-loop shaped p−type semiconductor regions becomes a region where voltage drop occurs, and a depletion layer expanding from pn-junction made of the p−type semiconductor region and the n−type semiconductor region pinches the current path, which is a neutral region of the n−type semiconductor region (the pinch effect), and consequently, if the current value increases, there is a possibility that a phenomenon that the resistance value increases may occur.

Further, in the latter of the above prior technique, since consideration for the controls of each element that determines the resistance value is not made, there is a problem that it is difficult to obtain a desired resistance value through preferable controllability.

It is, therefore, an object of the present invention to provide a technique to obtain a desired resistance value through preferable controllability, and improve linearity between voltage and current.

The above and other objects as well as novel features of the present invention will be readily apparent from the description of the specification and the accompanying drawings.

The outline of a representative one of the inventions to be disclosed in the present application is briefly explained as below.

That is, the present invention, has a main surface (first main surface), and is characterized by that on the first main surface of a semiconductor resistor layer (second semiconductor region) which works as a bulk resistor, a guard ring layer (third semiconductor region) of a conductive type opposite to the semiconductor resistor layer is formed, and a contact layer (fourth semiconductor region) that goes through the guard ring layer and is of a conductive type same as the semiconductor resistor layer, and has a higher impurity concentration than that of the semiconductor resistor layer and the guard ring layer is formed, and on the top of the contact layer and at the bottom of the semiconductor resistor layer, semiconductor regions (fifth semiconductor region and first semiconductor region) that make ohmic contact with electrodes and are of a conductive type same as the semiconductor resistor layer, and have an impurity concentration same as or higher than that of the contact layer are adjacently arranged respectively.

Effects to be obtained by a representative one of the inventions to be disclosed in the present application are briefly explained as below.

That is, according to the present invention, by forming the contact layer of a high impurity concentration to construct a semiconductor bulk resistor element going through the guard ring layer and adjacent to the semiconductor resistor layer, it is possible to suppress the variation of resistance value caused by the pinch effect with voltage application.

Further, according to the present invention, since a region where current flows is constant, it is possible to obtain a resistor element having a highly precise and stable resistance value with ease and preferable controllability.

Furthermore, according to the present invention, by connecting the semiconductor resistor layer to the high impurity concentration semiconductor region that makes ohmic contact with the electrodes, it is possible to reduce a contact resistance between electrode and semiconductor region.

### BRIEF DESCRIPTIONS OF THE DRAWINGS

FIG. 1A is a top view of a semiconductor chip with partly disassembled in a semiconductor bulk resistance element according to a first preferred embodiment.

FIG. 1B is a cross sectional view along A-A′ line of the semiconductor chip shown in FIG. 1A.

FIG. 2 is a cross sectional view for explaining the action of the semiconductor chip in the semiconductor bulk resistance element according to the first preferred embodiment.

FIG. 3A is a cross sectional view of the semiconductor chip in a semiconductor bulk resistance element shown in FIG. 1 after main manufacturing processes.

FIG. 3B is a cross sectional view of the semiconductor chip in a semiconductor bulk resistance element shown in FIG. 1 after main manufacturing processes.

FIG. 3C is a cross sectional view of the semiconductor chip in a semiconductor bulk resistance element shown in FIG. 1 after main manufacturing processes.

FIG. 3D is a cross sectional view of the semiconductor chip in a semiconductor bulk resistance element shown in FIG. 1 after main manufacturing processes.

FIG. 3E is a cross sectional view of the semiconductor chip in a semiconductor bulk resistance element shown in FIG. 1 after main manufacturing processes.

FIG. 4A is a top view of a semiconductor chip with partly disassembled in a semiconductor bulk resistance element according to a second preferred embodiment.

FIG. 4B is a cross sectional view along B-B′ line of the semiconductor chip shown in FIG. 4A.

FIG. 5A is a cross sectional view of the semiconductor chip in the semiconductor bulk resistance element shown in FIG. 4 after main manufacturing processes.

FIG. 5B is a cross sectional view of the semiconductor chip in the semiconductor bulk resistance element shown in FIG. 4 after main manufacturing processes.

FIG. 5C is a cross sectional view of the semiconductor chip in the semiconductor bulk resistance element shown in FIG. 4 after main manufacturing processes.

FIG. 5D is a cross sectional view of the semiconductor chip in the semiconductor bulk resistance element shown in FIG. 4 after main manufacturing processes.

FIG. 5E is a cross sectional view of the semiconductor chip in the semiconductor bulk resistance element shown in FIG. 4 after main manufacturing processes.

FIG. 6A is a cross sectional view of a semiconductor chip 102 in a semiconductor bulk resistance element according to a third preferred embodiment.

FIG. 6B is a cross sectional view of a semiconductor chip 103 in a semiconductor bulk resistance element according to a third preferred embodiment.

FIG. 6C is a cross sectional view of a semiconductor chip 104 in a semiconductor bulk resistance element according to a third preferred embodiment.

FIG. 6D is a cross sectional view of a semiconductor chip 105 in a semiconductor bulk resistance element according to a third preferred embodiment.

FIG. 7 is a schematic view with partly disassembled showing the outline of a semiconductor bulk resistance element according to a fourth preferred embodiment of the present invention, where semiconductor chips are sealed up with mold resin.

FIG. 8 is a top view with partly disassembled showing a diode module having a semiconductor bulk resistance element according to the fifth preferred embodiment.

FIG. 9 is a cross sectional view of substantial part of the diode module shown in FIG. 8.

### DESCRIPTIONS OF THE PREFERRED EMBODIMENTS

In the following preferred embodiments, at necessity, explanations are made with divided plural sections or preferred embodiments, however, unless otherwise specified, they are not mutually irrelevant, but one is in relations of a modified example, details, supplementary explanations and the like of part or whole of the other. Further, in the following preferred embodiments, in the case of reference to the number and the like of an element (including quantity, numeric value, amount, range and the like), unless otherwise specified or unless clearly limited in principle, the present invention is not limited to the specified number, and a number over or below the specified one may be used. In the same manner, in the following preferred embodiments, in the case of reference to the shape of a structural element and the like, positional relation and the like, unless otherwise specified or unless clearly limited in principle, the present invention substantially includes other shape and the like approximate to or similar to the shape or the like. The same goes for the aforementioned numeric value and range. Further, in all the drawings for explaining the preferred embodiments, in principle an identical symbol is allotted to a same component, and repeated explanations thereof are omitted. Preferred embodiments according to the present invention are illustrated in more details with reference to the attached drawings hereinafter.

### First Preferred Embodiment

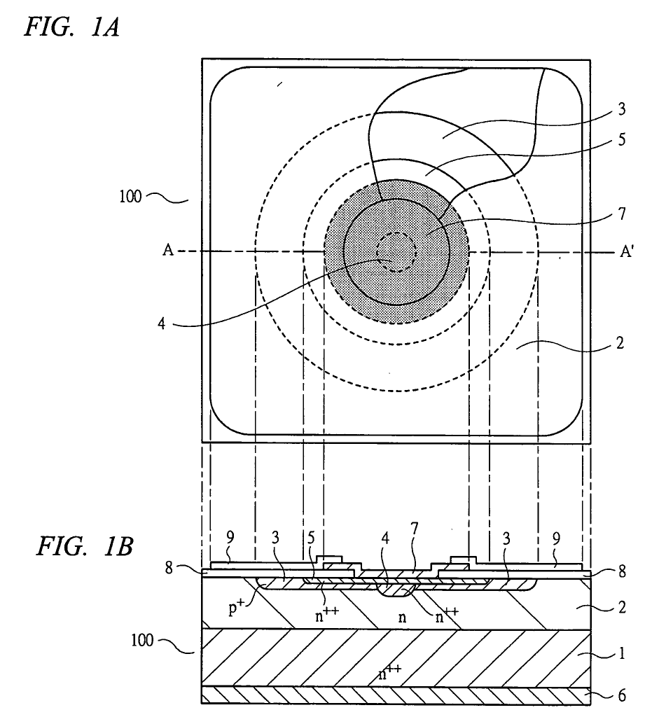

FIG. 1 shows a semiconductor chip 100 in a semiconductor bulk resistance element according to a first preferred embodiment, wherein FIG. 1A is a top view with partly disassembled, and FIG. 1B is a cross sectional view along A-A′ line of the semiconductor chip 100 shown in FIG. 1A.

In FIG. 1, the semiconductor chip 100 having a first main surface and a second main surface positioned on mutually opposite sides includes an n++ type semiconductor region 1 (first semiconductor region) which is n−type (first conductive type), having the second main surface and having a high concentration (first impurity concentration), and an n−type semiconductor region 2 (second semiconductor region) which is n−type, formed on the n++ type semiconductor region 1 by epitaxial method, and has the first main surface and has a second impurity concentration lower than that of the n++ type semiconductor region 1, a p+ type semiconductor region 3 (third semiconductor region) which is p−type (second conductive type), selectively formed from the first main surface to the second main surface of the n−type semiconductor region 2, and have a third impurity concentration higher than that of the n−type semiconductor region 2, an n++ type semiconductor region 4 (fourth semiconductor region) that is selectively formed from the first main surface to the second main surface of the p+ type semiconductor region 3, go through the p+ type semiconductor region 3, and is adjacent to the n−type semiconductor region 2, and has the third impurity concentration higher than that of the n−type semiconductor region 2 and that of the p+ type semiconductor region 3, and an n++ type semiconductor region 5 (fifth semiconductor region) which is n−type, selectively formed from the first main surface to the second main surface of the p+ type semiconductor region 3, and have a fifth impurity concentration higher than that of the p+ type semiconductor region 3 and same as or higher than that of the n++ type semiconductor region 4.

Meanwhile, the semiconductor chip 100 is formed so that the p+ type semiconductor region 3 exists between the n−type semiconductor region 2 and the n++ type semiconductor region 5 in all the portions of the first main surface.

Further, the semiconductor chip 100 has a second electrode 6 that is formed in a state of having ohmic contact with the n++ type semiconductor region 1 on the second main surface, and a first electrode 7 that is formed in a state of having ohmic contact with the n++ type semiconductor region 5 on the first main surface.

Furthermore, the semiconductor chip 100 has a first passivation film 8 formed of thermal oxidized SiO₂ film and phosphorous glass and the like, and a second passivation film 9 such as silicon nitride (P—SiN) and the like formed on the first passivation film 8 and the first electrode 7 and formed by plasma CVD method, and a part of the first electrode 7 exposes at the center portion of the semiconductor chip 100.

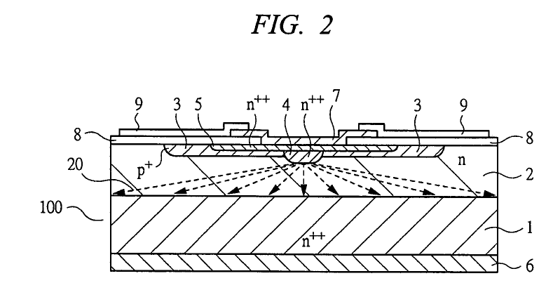

Next, characteristics of a semiconductor bulk resistance element equipped with the semiconductor chip 100 according to the first preferred embodiment are explained with reference to FIG. 2. FIG. 2 is a figure showing a flow of electrons as carriers in the semiconductor bulk resistance element equipped with the semiconductor chip 100 according to the first preferred embodiment.

When voltage at which the first electrode 7 becomes negative, and the second electrode 6 becomes positive is applied, electrons flow approximately in a direction of arrows shown by symbol 20 in FIG. 2. In this case, electrons flow in a path of the n++ type semiconductor region 5, the n++ type semiconductor region 4, the n−type semiconductor region 2, and the n++ type semiconductor region 1. The region that works as a resistor body in this current path is the n−type semiconductor region 2, and the other regions, such as the n++ type semiconductor region 5, the n++ type semiconductor region 4, and the n++ type semiconductor region 1, have low resistance, therefore, do not work as resistor bodies. That is, in these high impurity concentration regions, there is hardly a voltage drop and the potential in the respective impurity concentration regions is considered to be same, and a voltage drop occurs in the n−type semiconductor region 2, which works as a resistor body.

Accordingly, in the semiconductor bulk resistance element equipped with the semiconductor chip 100 according to the first preferred embodiment, since the structure as mentioned above is employed, a portion pinched by the p+ type semiconductor region 3 becomes a region where a voltage drop does not occur, therefore, it is possible to suppress a variation of resistance value caused by the pinch effect along with voltage application.

Meanwhile, a resistance value of electric conductor is proportional to a distance in advance direction of current, and reversely proportional to a cross sectional area, and this is the same in a resistance value of semiconductor. That is, in the case of the first preferred embodiment, when a area of the junction surface (second junction surface) of the n++ type semiconductor region 4 and the n−type semiconductor region 2 that works as a contact layer, that is, a junction area of n++type semiconductor region 4 is made large, the resistance value becomes small, and when a length of the flow 20 of electrons is made long, the resistance value becomes large.

Accordingly, in the semiconductor bulk resistance element equipped with the semiconductor chip 100 according to the first preferred embodiment, since the structure as mentioned above is employed, by controlling the impurity concentration of the n−type semiconductor region 2, the junction area of the n++ type semiconductor region 4, and the length of the electron flow 20 and the like, it is possible to obtain a semiconductor bulk resistance element having a desired resistance value with ease.

And, according to the first preferred embodiment, by forming the n++ type semiconductor region 5 having ohmic contact with the first electrode 7 and the n++ type semiconductor region 4 working as a contact layer individually, it is possible to control the junction area of the n++ type semiconductor region 4, without limitation of plane area viewed from the first main surface of the n++ type semiconductor region 5, and it is feasible to obtain a semiconductor bulk resistance element having a relatively large resistance value with ease.

Further, the p+ type semiconductor region 3 play a role as a guard ring layer for preventing electrons flowing from the n++ type semiconductor region 5 for making ohmic contact with the first electrode 7 from flowing in a side direction in the interface of the first passivation film 8 and the n−type semiconductor region 2. Accordingly, by arranging the p+ type semiconductor region 3 to exist as the guard ring layer between the n−type semiconductor region 2 and the n++ type semiconductor region 5 in all the portions on the first main surface, it is possible to make electron current flow between the first electrode and the second electrode accurately and precisely.

Further, since the n++ type semiconductor region 1 has ohmic contact with the second electrode 6, and the n++ type semiconductor region 5 has ohmic contact with the first electrode 7, it is possible to make electron current flow between the first electrode and the second electrode accurately and precisely.

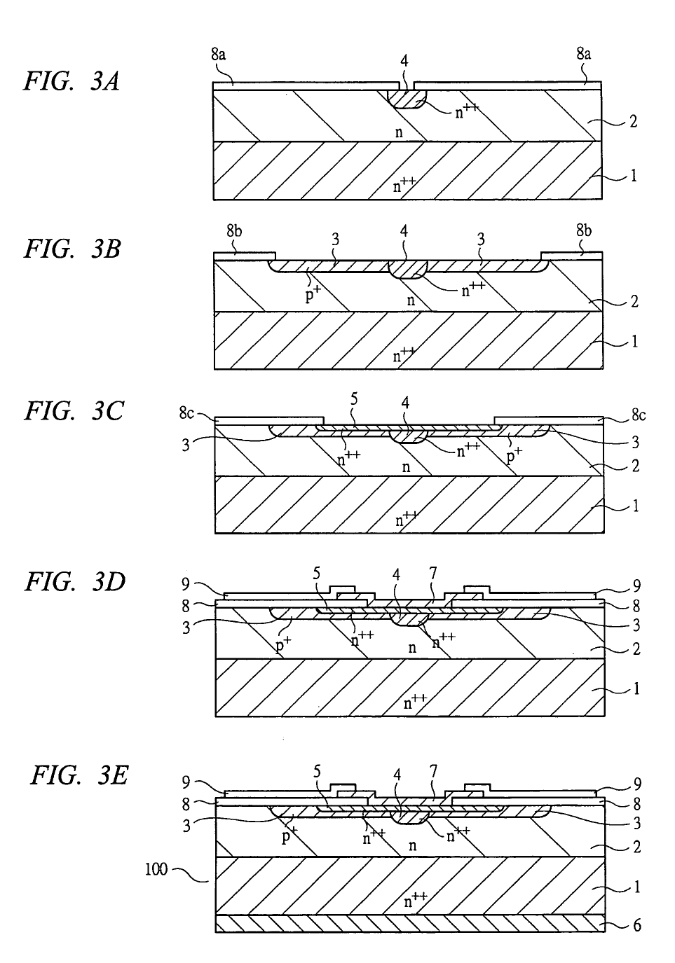

FIG. 3 shows cross sectional views, at each step of main manufacturing process for the semiconductor chip 100 equipped in the semiconductor bulk resistance element according to the first preferred embodiment shown in FIG. 1 and FIG. 2, and hereinafter, the manufacture method of the semiconductor chip 100 according to the first preferred embodiment is explained with reference to FIG. 3.

(a) On the n++ type semiconductor region 1 of 1×10¹⁸ cm⁻¹ to 1×10²⁰ cm⁻³ of high impurity concentration with for example phosphorous, antimony, arsenicum as impurities, the n− type semiconductor region 2 of 1×10¹⁴ cm⁻³ to 1×10¹⁸ cm⁻³ formed by epitaxial method is formed. On this n−type semiconductor region 2, an oxide film 8a is formed, and by normal photo etching, part of the oxide film 8a is removed, and the n++ type semiconductor region 4 is selectively formed with phosphorus of 1×10¹⁸ cm⁻³ to 1×10²⁰ cm⁻³ as impurity by thermal diffusion or ion implantation.

(b) Next, the oxide film 8a formed in (a) is removed once, and an oxide film 8b is newly formed and by normal photo etching, a window is made in the oxide film 8b. At the portion where the window is made in the oxide film 8b, the p+ type semiconductor region 3 is selectively formed with boron of 1×10¹⁷ cm⁻³ to 1×10¹⁹ cm⁻³ as impurity by thermal diffusion or ion implantation.

Herein, in the case of doping impurity by thermal diffusion, by setting the order of respective steps as in the first preferred embodiment, it is possible to shorten heat treatment time. That is, if the n++ type semiconductor region 4 is formed before the p+ type semiconductor region 3, by difference of diffusion coefficients of respective impurities, irrespective of heat treatment time, it is possible to form the n++ type semiconductor region 4 so as to completely go through the p+ type semiconductor region 3. However, when the p+ type semiconductor region 3 is formed before the n++ type semiconductor region 4, unless certain heat treatment time corresponding to difference of diffusion coefficients of respective impurities passes, it is not possible to form the n++ type semiconductor region 4 so as to completely go through the p+ type semiconductor region 3.

(c) Next, the oxide film 8b formed in (b) is removed once, and an oxide film 8c is newly formed and by normal photo etching, a window is made in the oxide film 8c. At the portion where the window is made in the oxide film 8c, the n++ type semiconductor region 5 is selectively formed with phosphorus of 1×10¹⁸ cm⁻³ to 1×10²⁰ cm⁻³ as impurity by thermal diffusion or ion implantation.

(d) The oxide film 8c formed in the above step is removed once, and an oxide film is newly formed by thermal oxidization method or CVD method, or with the oxide film 8c left, the first passivation film 8 on which a phosphorous glass (PSG) film is formed is formed on the oxide film, then a window is made in the first passivation film 8 by photo etching, and aluminum or aluminum including silicon is deposited on the surface, and by normal photo etching, the first electrode 7 is formed. Thereafter, the second passivation film 9 as a plasma silicon nitride film is formed on the surface, and patterning is made by normal photo etching, and part of the first electrode 7 is exposed.

At this moment, as shown in FIG. 1A, if the exposed portion of the first electrode 7 is located in a center portion of the semiconductor chip 100 viewed from the first main surface, extracting electrodes such as wire bonding and the like becomes easy, and on completion as a semiconductor bulk resistance element, it is possible to largely reduce failures caused by positional displacement of electrode and wire.

(e) Finally, a gold or gold—antimony electrode is deposited on a back surface, and after deposition, heat treatment at 300° C. to 450° C. is made and the second electrode 6 is formed, and the semiconductor chip 100 is completed.

### Second Preferred Embodiment

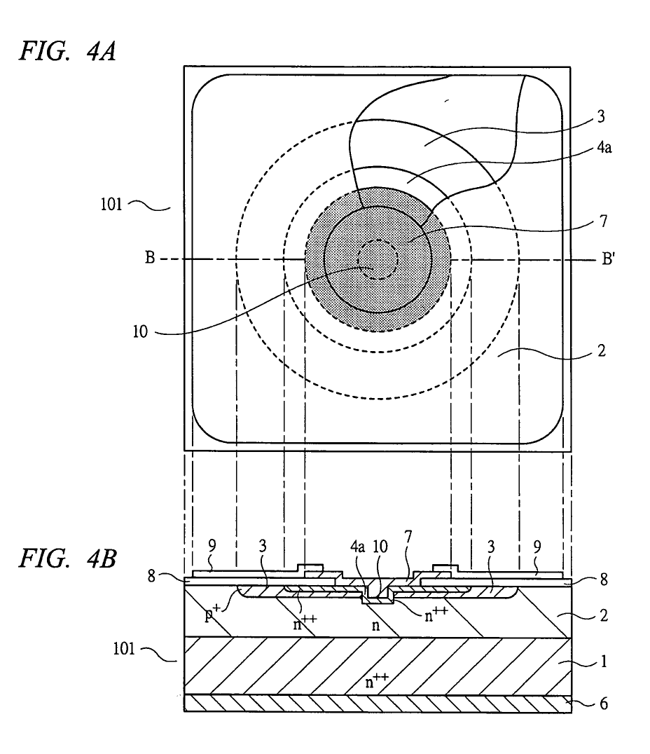

FIG. 4 shows a semiconductor chip 101 in a semiconductor bulk resistance element according to a second preferred embodiment, wherein FIG. 4A is a top view with partly disassembled, and FIG. 4B is a cross sectional view along B-B′ line of the semiconductor chip 101 shown in FIG. 4A. In FIG. 4, explanations of the same reference symbols as those in FIG. 1 are omitted.

In the semiconductor chip 100 shown in FIG. 1, the n++type semiconductor region 4 that is selectively formed so as to go through the p+ type semiconductor region 3, from the first main surface to the second main surface of the p+ type semiconductor region 3 is formed, meanwhile in the semiconductor chip 101 shown in FIG. 4, an n++ type semiconductor region 4 does not exist, but there are a concave shaped region 10 arranged from a first main surface of a p+ type semiconductor region 3 to a second main surface, and an n++ type semiconductor region 4a (sixth semiconductor region), which is n−type, that includes a exposed inside of the concave shaped region 10 and part of the p+ type semiconductor region 3, and is selectively formed from the first main surface to the second main surface, and has a sixth impurity concentration higher than that of the p+ type semiconductor region 3 and that of an n−type semiconductor region 2, is formed so as to contact with the p+ type semiconductor region 3 and the n−type semiconductor region 2. In this point, the second preferred embodiment is different from the first preferred embodiment shown in FIG. 1.

Further, in FIG. 1B, the n++ type semiconductor region 5 having ohmic contact with the first electrode 7 is formed, but in FIG. 4B, an n++ type semiconductor region 5 does not exist, but the n++ type semiconductor region 4a have ohmic contact with a first electrode 7, which is also different from the first preferred embodiment shown in FIG. 1.

That is, in the second preferred embodiment, the n++ type semiconductor region 4a has both the function as a contact layer (the function of the n++ type semiconductor region 4 in the first preferred embodiment), and the function for making ohmic contact with the first electrode 7 (the function of the n++ type semiconductor region 5 in the first preferred embodiment).

Accordingly, in the semiconductor bulk resistance element equipped with the semiconductor chip 101 according to the second preferred embodiment, since the structure as mentioned above is employed, in comparison with the first preferred embodiment, even if one process (the process of forming the n++ type semiconductor region 5) is omitted, it is possible to obtain a semiconductor bulk resistance element having the same characteristics as those in the first preferred embodiment.

Note that, the semiconductor chip 101 is formed so that in all the portions on the first main surface, the p+ type semiconductor region 3 exists between the n−type semiconductor region 2 and the n++ type semiconductor region 4a.

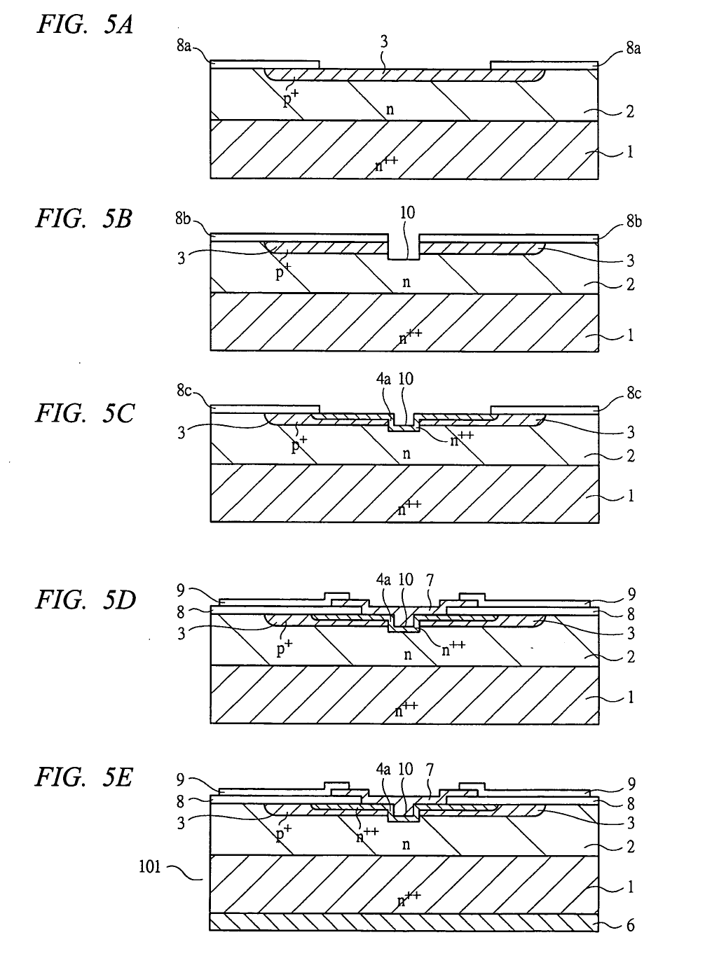

FIG. 5 shows cross sectional views, at each step of main manufacturing process for the semiconductor chip 101 equipped in the semiconductor bulk resistance element according to the second preferred embodiment shown in FIG. 4, and hereinafter, the manufacture method of the semiconductor chip 101 according to the second preferred embodiment is explained with reference to FIG. 5.

(a) On an n++ type semiconductor region 1 of 1×10¹⁸ cm⁻³ to 1×10²⁰ cm⁻³ of high impurity concentration with impurities such as, for example, phosphorous, antimony, arsenicum, the n−type semiconductor region 2 of 1×10¹⁴ cm⁻³ to 1×10¹⁸ cm⁻³ formed by epitaxial method is formed. On this n−type semiconductor region 2, an oxide film 8a is formed, and by normal photo etching, part of the oxide film 8a is removed, and the p+ type semiconductor region 3 is selectively formed with boron of 1×10¹⁷ cm⁻³ to 1×10¹⁹ cm⁻³ as impurity by thermal diffusion or ion implantation.

(b) Next, the oxide film 8a formed in (a) is removed once, and an oxide film 8b is newly formed and by normal photo etching, a window is made in the oxide film 8b. From the portion where the window is made in the oxide film 8b, the p+ type semiconductor region 3 is removed by dry etching or alkali etching using KOH or NaOH and the concave shaped area 10 is formed so that the n−type semiconductor region 2 should be exposed.

In order to obtain a shape of the concave shaped area 10 by alkali etching, a plane direction of the n−type semiconductor region 2 is made to <−100> plane, and though not illustrated, an etched shape of the oxide film 8b (the shape of the concave shaped area 10 viewed from the first main surface) is made to be a square, and by carrying out an alkali etching including KOH or NaOH a shape where the side surface of the concave shaped area 10 shown in FIG. 5B is etched vertically can be obtained. For example, by carrying out the alkali etching with alkali water solution whose NaOH or KOH concentration is 5 wt % to 65 wt %, temperature is 25° C. to 115° C., a shape whose side surface is (111) plane and cross section is etched vertically can be obtained.

In the case where the shape of the concave shaped area 10 is obtained by dry etching, the shape of etching the oxide film 8b (the shape of the concave shaped area 10 viewed from the first main surface) can be made a circle, as shown in FIG. 4A. Further, in the case where the shape of the concave portion area 10 is obtained by dry etching, since the control of the length of the concave shaped area 10 from the first main surface to the direction of the n++ semiconductor region 1 (the depth of the concave shaped area 10) is relatively easier than the case using alkali etching, it is possible to control a length of the electron flow 20 with ease.

(c) Next, the oxide film 8b formed in (b) is removed once, and an oxide film 8c is newly formed and by normal photo etching, a window is made in the oxide film 8c. At a portion where the window is made in the oxide film 8c, the n++ type semiconductor region 4a is selectively formed with phosphorous of 1×10¹⁸ cm⁻³ to 1×10²⁰ cm⁻³ as impurity by thermal diffusion or ion implantation.

According to the second preferred embodiment, after the p+ type semiconductor region 3 is formed, the concave shaped area 10 is formed by etching, and then the n++ type semiconductor region 4a is formed on an area including a bottom surface and all the side surfaces of the concave shaped area 10 and part of the p+ type semiconductor region 3, therefore, it is possible to form the n++ type semiconductor region 4a so as to precisely go through the p+ type semiconductor region 3, and contact with the n−type semiconductor region 2.

(d) The oxide film 8c formed in the above step is removed once, and an oxide film is newly formed by thermal oxidization method or CVD method, or with the oxide film 8c left, a first passivation film 8 on which a phosphorous glass (PSG) film is formed is formed on the oxide film, then a window is made in the first passivation film 8 by photo etching, and aluminum or aluminum including silicon is deposited on a surface, and by normal photo etching, the first electrode 7 is formed. Thereafter, a second passivation film 9, which is a plasma silicon nitride film, is formed on a surface, and patterning is made by normal photo etching, and part of the first electrode 7 is exposed.

(e) Finally, a gold or gold—antimony electrode is deposited on the back surface, and after deposition, heat treatment at 300° C. to 450° C. is made and a second electrode 6 is formed, and the semiconductor chip 101 is completed.

### Third Preferred Embodiment

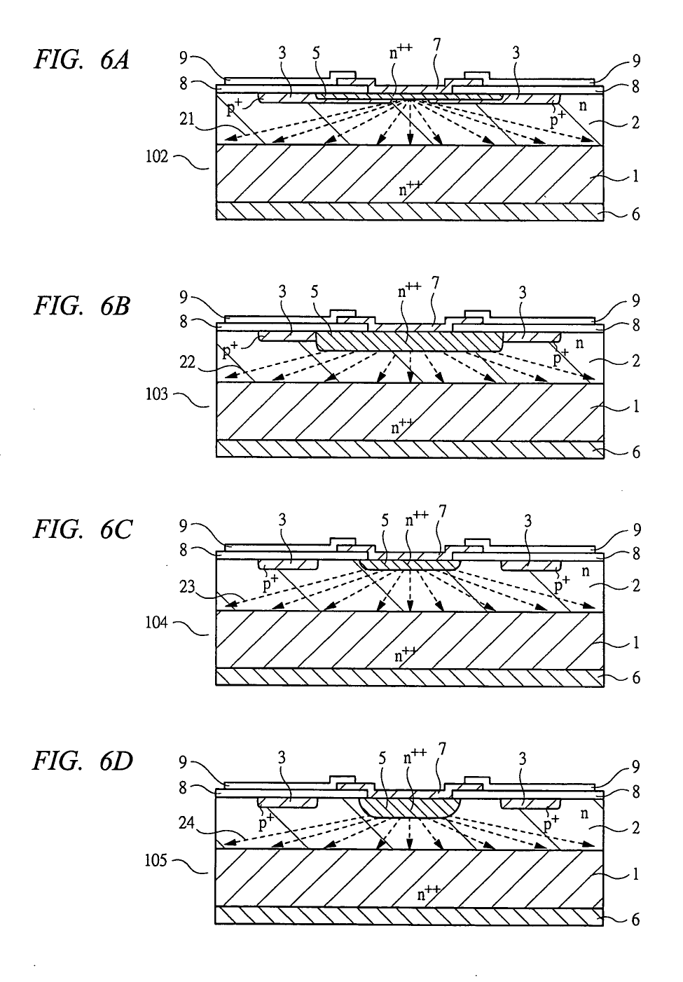

FIG. 6 shows semiconductor chips 102, 103, 104, 105 in a semiconductor bulk resistance element according to a third preferred embodiment, wherein FIG. 6A shows the semiconductor chip 102, FIG. 6B shows the semiconductor chip 103, FIG. 6C shows the semiconductor chip 104, and FIG. 6D shows the semiconductor chip 105. In FIG. 6, explanations of the same reference symbols as those in FIG. 1 are omitted. Note that, in FIG. 6, for explaining the action of the semiconductor bulk resistance element according to the third preferred embodiment, the flows 21, 22, 23, 24 of electrons as carriers are illustrated in the same manner as in FIG. 2. Hereinafter, the characteristics of the semiconductor bulk resistance element according to the third preferred embodiment are explained with reference to FIG. 6.

In FIG. 6A, the n++ type semiconductor region 4 of the semiconductor chip 100 shown in FIG. 2 is deleted. Accordingly, in FIG. 6A, when voltage at which a first electrode 7 becomes negative, and a second electrode 6 becomes positive is applied, electrons flow approximately in a direction of arrows shown by reference symbol 21 in the figure. In this case, electrons flow in a path of an n++ type semiconductor region 5, an n−type semiconductor region 2, and an n++ type semiconductor region 1. The region that works as a resistor body in this current path is the n−type semiconductor region 2, and the other regions, such as the n++ type semiconductor region 5, the n++ type semiconductor region 1, have low resistance, do not work as resistor bodies. In FIG. 6A, a voltage drop occurs in the n−type semiconductor region 2 that works as a resistor body.

Herein too, a p+ semiconductor region 3 formed into a ring shape (for example, donut shape) plays a role as a guard ring layer for preventing electrons flowing from the n++ type semiconductor region 5 for making ohmic contact with the first electrode 7 from flowing in the side direction in the interface of a first passivation film 8 and the n−type semiconductor region 2.

In FIG. 6A, among the n−type semiconductor region 2 which works as a resistor body, a portion being just under the n++type semiconductor region 5 and pinched by the p+ type semiconductor region 3 which become this guard ring layer, becomes a region where voltage drop occurs, and a depletion layer expanding from pn-junction made of the p+ type semiconductor region 3 and the n−type semiconductor region 2 pinches a neutral region of the n−type semiconductor region 2 as the current path (the pinch effect), and consequently, when the current value increases, there is a possibility that the resistance value varies more easily (becomes higher) than the first or second preferred embodiment.

However, since the p+ type semiconductor region 3 to become this guard ring layer is formed in a ring shape so as to exist between the n−type semiconductor region 2 and the n++type semiconductor region 5 in all portions on a first main surface, it is possible to make electron current flow between the first electrode and the second electrode accurately and precisely. Further, since the n++ type semiconductor region 1 has ohmic contact with the second electrode 6, and the n++ type semiconductor region 5 has ohmic contact with the first electrode 7, it is possible to make electron current flow between the first electrode and the second electrode accurately and precisely.

FIG. 6B shows the semiconductor chip 103 as a modified example of the semiconductor chip 102 shown in FIG. 6A. The semiconductor chip 103 shown in FIG. 6B is characterized by that the n++ type semiconductor region 5 of the semiconductor chip 102 shown in FIG. 6A is formed so as to go through the p+ semiconductor region 3.

Accordingly, in FIG. 6B, when voltage at which the first electrode 7 becomes negative, and the second electrode becomes positive is applied, electrons flow approximately in a direction of arrows shown by reference symbol 22 in the figure, and electrons flow in a path of the n++ type semiconductor region 5, the n−type semiconductor region 2, the n++ type semiconductor region 1 in the same manner as in (a). The region that works as a resistor body in this current path is the n−type semiconductor region 2, and the other regions such as the n++ type semiconductor region 5, the n++ type semiconductor region 1, have low resistance, do not work as resistor bodies. In FIG. 6B, a voltage drop occurs in the n−type semiconductor region 2 which works as a resistor body.

Therefore, in FIG. 6B, the n++ type semiconductor region 5 of the semiconductor chip 102 shown in FIG. 6A is formed so as to go through the p+ type semiconductor region 3, thereby it is possible to suppress the influence of the pinch effect. Accordingly, even in comparison with the first or second preferred embodiment, a variation degree of the resistance value due to the increase of current value is roughly same. Further, since the p+ semiconductor region 3 to become the guard ring layer is formed, and it has ohmic contact with the first electrode 7 and the second electrode 6, it is possible to make electron current flow between the first electrode and the second electrode accurately and precisely.

Herein, when the semiconductor chip 103 shown in FIG. 6B is compared with the semiconductor chip 100 or 101 shown in the first or second preferred embodiment, since the n++ semiconductor region 5 has both the function to make ohmic contact with the first electrode 7 and the function to work as a contact layer, a number of manufacture processes can be reduced by one, but it causes a limitation of plane area viewed from the first main surface of the n++ type semiconductor region 5, and a resistance value to be obtained becomes small. Accordingly, it may be called an effective embodiment in the case where a desired resistance value is relatively small.

FIG. 6C shows the semiconductor chip 104 as a modified example of the semiconductor chip 102 shown in FIG. 6A. In FIG. 6C, different from (a), the p+ type semiconductor region 3 to become the guard ring layer is formed separately from the n++type semiconductor region 5 of the contact layer via the n−type semiconductor region 2. Even if it is separated, electrons flow in a direction of arrows shown by reference symbol 23 in the figure, in a path of the n++ type semiconductor region 5, the n−type semiconductor region 2, the n++ type semiconductor region 1. The region that works as a resistor body in this current path is the n−type semiconductor region 2 in the same manner as shown in FIG. 6(A), and the other regions, such as the n++ type semiconductor region 5, the n++ type semiconductor region 1, have low resistance, do not work as resistor bodies. In FIG. 6C, a voltage drop occurs also in the n−type semiconductor region 2 works as a resistor body.

Herein too, as explained in FIG. 6A, when current flows, a depletion layer expanding from the pn-junction made of the p+ type semiconductor region 3 and the n−type semiconductor region 2 pinches the neutral region of the n−type semiconductor region 2, which is the current path (the pinch effect), and consequently, when the current value increases, there is a possibility that the resistance value varies more easily (becomes higher) than the first or second preferred embodiment.

However, since the p+ type semiconductor region 3 to become the guard ring layer is formed, and has ohmic contact with the first electrode 7 and the second electrode 6, it is possible to make electron current flow between the first electrode and the second electrode accurately and precisely.

FIG. 6D shows the semiconductor chip 105 as a modified example of the semiconductor chip 104 shown in FIG. 6C. The semiconductor chip 105 shown in FIG. 6D is characterized by that a distance between a junction surface, made of the p+ type semiconductor region 3 and the n−type semiconductor region 2 of the semiconductor chip 104 shown in FIG. 6C, and a first main surface is same as or shorter than a distance between a junction surface, made of the n++ type semiconductor region 5 and the n−type semiconductor region 2, and the first main surface.

Accordingly, in FIG. 6D, when voltage at which the first electrode 7 becomes negative, and the second electrode 6 becomes positive is applied, electrons flow approximately in a direction of arrows shown by reference symbol 24 in the figure, and electrons flow in a path of the n++ type semiconductor region 5, the n−type semiconductor region 2, the n++ type semiconductor region 1 in the same manner as in FIG. 6A. The region that works as a resistor body in this current path is the n−type semiconductor region 2, and the other regions such as the n++ type semiconductor region 5 and the n++ type semiconductor region 1, being have resistance, do not work as resistor bodies. In FIG. 6D, a voltage drop occurs in the n−type semiconductor region 2, which works as a resistor body.

Therefore, in FIG. 6D, a distance between a junction surface, made of the p+ type semiconductor region 3 and the n−type semiconductor region 2 of the semiconductor chip 104 shown in FIG. 6C, and the first main surface is the same as or shorter than a distance between a junction surface, made of the n++ type semiconductor region 5 and the n−type semiconductor region 2, and the first main surface, thereby it is possible to suppress the influence of the pinch effect. Accordingly, even in comparison with the first or second preferred embodiment, a variation degree of the resistance value caused by an increase of current value is roughly the same. Further, since the p+ semiconductor region 3 to become the guard ring layer is formed, and it has ohmic contact with the first electrode 7 and the second electrode 6, it is possible to make electron current flow between the first electrode and the second electrode accurately and precisely.

Herein, when the semiconductor chip 105 shown in FIG. 6D is compared with the semiconductor chip 100 or 101 shown in the first or second preferred embodiment, since the n++ semiconductor region 5 has both a function to make ohmic contact the first electrode 7 and a function to work as a contact layer, a number of manufacture processes can be reduced by one, but it causes a limitation of plane area viewed from the first main surface of the n++ type semiconductor region 5, and a resistance value to be obtained becomes small. Accordingly, it may be called an effective embodiment in the case where a desired resistance value is relatively small.

### Fourth Preferred Embodiment

FIG. 7 is a schematic figure showing a semiconductor bulk resistance element 110 where semiconductor chips according to a fourth preferred embodiment of the present invention are sealed up with mold resin. In FIG. 7, reference symbols 100, 101, 102, 103, 104, 105 are semiconductor chips explained in the first to the third preferred embodiments, a second electrode 6 of a second main surface of the semiconductor chip is connected to a second lead electrode 11b via solder 12, a wire 13 connects a first electrode 7 of the first surface of semiconductor chip and a first lead electrode 11a by wire bonding. Further, except part of the first lead electrode 11a and the second lead electrode 11b, the entire is sealed with a mold resin 14a, and a surface package type semiconductor bulk resistance element 110 is completed.

According to the present preferred embodiment, it is possible to assemble a semiconductor bulk resistance element in a small package whose volume is, for example, 1 mm³ or below, and accordingly, it is possible to make a product compact and lightweight.

Meanwhile, in the first to the third preferred embodiments explained heretofore, for the convenience of explanation, 100, 101, 102, 103, 104, 105 have been explained as semiconductor chips, and a mold resin sealing these semiconductor chips has been explained as the semiconductor bulk resistance element 110 in the fourth preferred embodiment, however, it is needless to mention that the semiconductor chips 100, 101, 102, 103, 104, 105 themselves may be made semiconductor bulk resistance elements.

### Fifth Preferred Embodiment

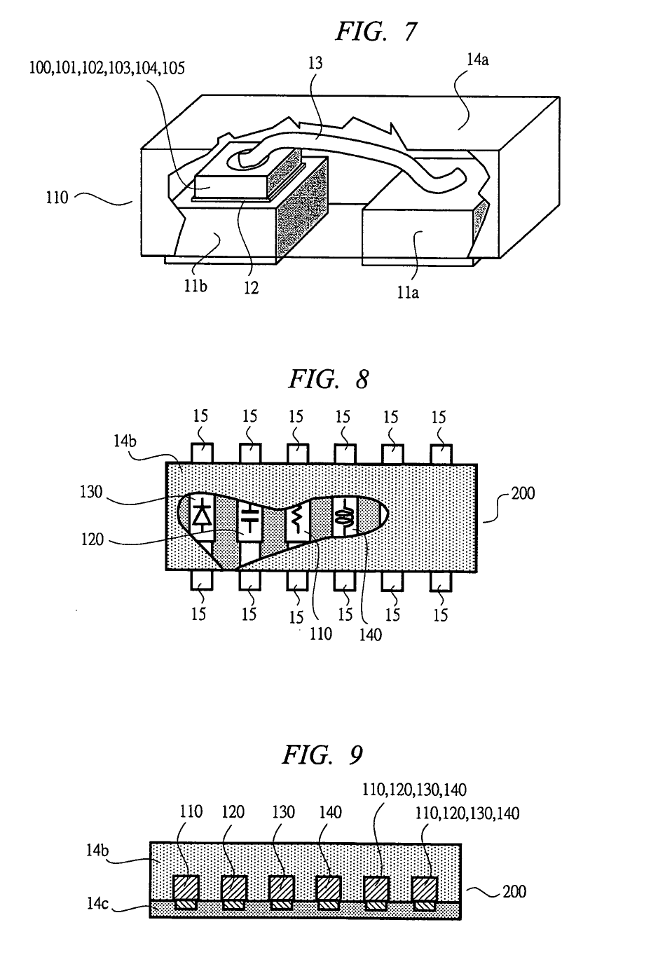

FIG. 8 and FIG. 9 show a diode module 200 according to a fifth preferred embodiment. FIG. 8 shows an example in which a capacitor 120 having the same package as in FIG. 7, passive parts such as an inductor 140 and a diode 130, in addition to the surface package type semiconductor bulk resistance element 110 explained in FIG. 7, are assembled into the diode module 200. FIG. 9 shows a cross sectional view of the module shown in FIG. 8. In FIG. 8, an object pointed by a symbol 15 is a lead electrode in the case of use as a module, and this lead electrode 15 is connected, for example, to a first lead electrode 11a, a second lead electrode 11b of the surface package type semiconductor bulk resistance element 110 shown in FIG. 7 via solder 12. With regard to other passive parts, that is, the capacitor 120, the inductor 140, and the diode 130, in the same manner, by connecting lead electrode of parts and the lead electrode 15 of module, the diode module 200 can be completed.

In all of these passive parts such as the capacitor, the inductor, the diode and the like, along with the spread of recent mobile apparatuses, have been made into modules. As mentioned above, the semiconductor bulk resistance element 110 explained in the fourth preferred embodiment is suitable for small size product, and suitable for constructing a module incorporating passive parts, that is, capacitor and inductor, or diode or the like (for example, the diode module 200 shown in the fifth preferred embodiment).

Heretofore, while the invention made by the inventors has been described concretely based on the embodiment, the invention is not limited to the embodiment. As a matter of course, various modifications can be made to the invention without departing from the spirit and scope of the invention.

For example, in the present invention, for making explanations easy, the conductive types of respective semiconductor regions are specified, however, even if the conductive types of semiconductors are changed, effects are not lost, but the characteristics of the present invention can be performed thoroughly. In FIG. 1, for example, 1 may be a p++type semiconductor region (first semiconductor region) of a high impurity concentration, 2 may be a p−type semiconductor region (second semiconductor region) formed by epitaxial method on the p++ type semiconductor region 1, 3 may be an n+ type semiconductor region (third semiconductor region) selectively formed on the p−type semiconductor region 2, 4 may be a p++type semiconductor region (fourth semiconductor region) selectively formed so as to go through the n+ type semiconductor region 3 from the center portion of the surface of the n+ type semiconductor region 3, and 5 may be a p++ type semiconductor region selectively formed from the surface of the n+ type semiconductor region 3, and the p++ type semiconductor region 5 may be formed so as to contact the p++ type semiconductor region 4 and the n+ semiconductor region 4.

The present invention, being a compact and lightweight resistance element using semiconductors, may be applied to a semiconductor bulk resistance element used in communication field, and an ultra compact module having a diode and a capacitor and the like.

What is claimed is:

1. A semiconductor bulk resistance element comprising a semiconductor chip having a first main surface and a second main surface positioned on mutually opposite sides, the semiconductor chip comprising:
a first semiconductor region having the second main surface and has a first impurity concentration and is of a first conductive type;
a second semiconductor region that is formed on the first semiconductor region, and has the first main surface and has a second impurity concentration lower than the first impurity concentration and is of the first conductive type;
a third semiconductor region that is selectively formed from the first main surface to the second main surface of the second semiconductor region, and has a third impurity concentration higher than the second impurity concentration and is of a second conductive type;
a fourth semiconductor region that is selectively formed so as to go through the third semiconductor region from the first main surface to the second main surface of the third semiconductor region and to be adjacent to the second semiconductor region, and has a fourth impurity concentration higher than the second impurity concentration and the third impurity concentration and is of the first conductive type;
a fifth semiconductor region that is selectively formed so as to go from the first main surface to the second main surface of the third semiconductor region, and to be adjacent to the third semiconductor region and the fourth semiconductor region, and has a fifth impurity concentration higher than the third impurity concentration and same as or higher than the fourth impurity concentration and is of the first conductive type;
a first electrode that is formed in a state of having ohmic contact with the fifth semiconductor region in the first main surface; and
a second electrode that is formed in a state of having ohmic contact with the first semiconductor region in the second main surface.

2. The semiconductor bulk resistance element according to claim 1,
wherein a distance between a first junction surface, made of the third semiconductor region and the second semiconductor region, and the first main surface is shorter than a distance between a second junction surface, made of the fourth semiconductor region and the second semiconductor region, and the first main surface.

3. The semiconductor bulk resistance element according to claim 2,
wherein the third semiconductor region exists between the second semiconductor region and the fifth semiconductor region on the first main surface.

4. A semiconductor bulk resistance element comprising a semiconductor chip having a first main surface and a second main surface positioned on mutually opposite sides, the semiconductor chip comprising:
a first semiconductor region that has the second main surface and has a first impurity concentration and is of a first conductive type;
a second semiconductor region that is formed on the first semiconductor region, and has the first main surface and has a second impurity concentration lower than the first impurity concentration and is of the first conductive type;
a third semiconductor region that is selectively formed from the first main surface to the second main surface of the second semiconductor region, and has a third impurity concentration higher than the second impurity concentration and is of a second conductive type;
a concave shaped portion that is formed on the first main surface of the third semiconductor region;
a sixth semiconductor region that includes the inside surface of the concave shaped portion and is selectively formed from the first main surface to the second main surface of the third semiconductor region so as to contact with the third semiconductor region and the second semiconductor region, and has a sixth impurity concentration higher than the third impurity concentration and the second impurity concentration and is of the first conductive type;
a first electrode that is formed in a state of having ohmic contact with the sixth semiconductor region in the first main surface; and
a second electrode that is formed in a state of having ohmic contact with the first semiconductor region in the second main surface.

5. The semiconductor bulk resistance element according to claim 4,
wherein a distance between a first junction surface, made of the third semiconductor region and the second semiconductor region, and the first main surface is shorter than a distance between a second junction surface, made of the sixth semiconductor region and the second semiconductor region, and the first main surface.

6. The semiconductor bulk resistance element according to claim 4,
wherein the third semiconductor region exists between the second semiconductor region and the sixth semiconductor region on the first main surface.

7. The semiconductor bulk resistance element according to claim 1,
wherein the first electrode is positioned at the center portion of the semiconductor chip viewed from the first main surface.

8. A semiconductor bulk resistance element comprising a semiconductor chip having a first main surface and a second main surface positioned on mutually opposite sides, the semiconductor chip comprising:
a first semiconductor region that has the second main surface and has a first impurity concentration and is of a first conductive type;
a second semiconductor region that is formed on the first semiconductor region, and has the first main surface and has a second impurity concentration lower than the first impurity concentration and is of the first conductive type;
a third semiconductor region that is formed selectively and in a ring shape from the first main surface to the second main surface of the second semiconductor region, and has a third impurity concentration higher than the second impurity concentration and is of a second conductive type;
a fifth semiconductor region that is selectively formed from the first main surface to the second main surface of the third semiconductor region so as to be adjacent to the third semiconductor region and the second semiconductor region, and has a fifth impurity concentration higher than the second impurity concentration and the third impurity concentration and is of the first conductive type;
a first electrode that is formed in a state of having ohmic contact with the fifth semiconductor region in the first main surface; and
a second electrode that is formed in a state of having ohmic contact with the first semiconductor region in the second main surface.

9. A semiconductor bulk resistance element comprising a semiconductor chip having a first main surface and a second main surface positioned on mutually opposite sides, the semiconductor chip comprising:
a first semiconductor region that has the second main surface and has a first impurity concentration and is of a first conductive type;
a second semiconductor region that is formed on the first semiconductor region, and has the first main surface and has a second impurity concentration lower than the first impurity concentration and is of the first conductive type;
a third semiconductor region that is formed selectively and in a ring shape, from the first main surface to the second main surface of the second semiconductor region, and has a third impurity concentration higher than the second impurity concentration and is of a second conductive type;
a fifth semiconductor region that is selectively formed from the first main surface to the second main surface, so as to be separated from the third semiconductor region, and to be adjacent to the second semiconductor region, and has a fifth impurity concentration higher than the second impurity concentration and the third impurity concentration and is of the first conductive type;
a first electrode that is formed in a state of having ohmic contact with the fifth semiconductor region in the first main surface; and
a second electrode that is formed in a state of having ohmic contact with the first semiconductor region in the second main surface.
